(19) United States
(12) Patent Application Publication
(10) Pub. No.: US 2009/0159990 A1
(43) Pub. Date: Jun. 25, 2009

(54) SEMICONDUCTOR DEVICE AND METHOD OF MANUFACTURING THE SAME

(76) Inventors: Hyung-Jin Park, Jungnang-gu (KR); Mun-Sub Hwang, Yussong-gu (KR)

Correspondence Address: SHERR & VAUGHN, PLLC, 620 HERNDON PARKWAY, SUITE 200, HERNDON, VA, 20170, US

(21) Appl. No.: 12/334,501

(22) Filed: Dec. 14, 2008

(30) Foreign Application Priority Data
Dec. 24, 2007 (KR) 10-2007-0136209

(51) Int. Cl. H01L 21/336; H01L 29/78

(52) U.S. Cl. 257/408; 438/301; 257/E21.433; 257/E29.266

(57) ABSTRACT

A semiconductor device and/or a method of manufacturing the same that may include: Forming a gate insulating film over a semiconductor substrate in a gate region. Forming a first gate pattern over the gate insulating film. Forming a second gate pattern over the first gate pattern, such that the second gate pattern is wider than the first gate pattern. Forming sidewall spacers at both sides of the first gate pattern and the second gate pattern, such that spaces are formed between the sidewall spacers and the first gate pattern below the second gate pattern.

The present application claims priority under 35 U.S.C. 119 and 35 U.S.C. 365 to Korean Patent Application No. 10-2007-0136209 (filed on Dec. 24, 2007), which is hereby incorporated by reference in its entirety.

### BACKGROUND

In recent years the size of integrated circuits has gradually reduced. This miniaturization in integrated circuits may involve a reduction in the size of transistors, including lightly doped drain (hereinafter, referred to as an “LDD”) regions and gate regions.

FIG. 1A illustrates an example structure of a transistor including a LDD region. As illustrated in FIG. 1B, portion 6 and the gate region may overlap. As illustrated in FIG. 1A, the process of forming LDD region 2 in semiconductor substrate 1 may include forming a gate region with a gate oxide film 3 and a gate poly 5, and then forming spacers at both sides of the gate poly 5.

The trend towards miniaturization of semiconductor devices has also brought about a reduction in size of the spacers 4. The small-sized spacers 4 may cause complications. For example, parasitic capacitance may be generated in portion 6 where a LDD region and a gate region overlap. As illustrated in FIG. 1B, the overlap between LDD region 2 and gate oxide film 3 may cause generation of overlap capacitance 6a and the overlap between gate poly 5 and LDD region 2 may cause generation of fringing capacitance 6b. Parasitic capacitance may cause problems in circuit design by making it difficult to estimate capacitances of semiconductor devices, which may make it difficult to match DC/AC parameters.

### SUMMARY

Embodiments relate to a semiconductor device and a method of manufacturing the same. Embodiments may prevent generation of parasitic capacitance caused by miniaturization of semiconductor devices in a portion where an LDD region and a gate region overlap. Embodiments may prevent overlap capacitance and fringing capacitance. For example, in embodiments, fringing capacitance generated by overlap of an LDD region and a gate region in a miniaturized semiconductor device may be minimized or substantially eliminated.

Additional advantages, objects, and features of embodiments will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

Embodiments relate to a method of manufacturing a semiconductor device that may include at least one of the following steps: Forming a gate insulating film in a gate region on and/or over a semiconductor substrate. Forming a first gate pattern on and/or over a gate insulating film. Forming a second gate pattern on and/or over the first gate pattern, such that the second gate pattern is wider than the first gate pattern. Forming sidewall spacers at both sides of the first and second gate patterns, such that the sidewall spacers extend substantially perpendicular to the surface of the semiconductor substrate and/or along a side surface of the second gate pattern.

In embodiments, forming a second gate pattern may include at least one of the following steps: Forming a sacrificial film over the surface of the semiconductor substrate including the first gate pattern. Planarizing the sacrificial film such that the upper surface of the first gate pattern is exposed. Forming a gate poly on and/or over the planarized sacrificial film. Forming a mask pattern on and/or over the gate poly, such that the mask pattern is wider than the first gate pattern. Etching the gate poly and the sacrificial film using the mask pattern. Removing the mask pattern. Removing the sacrificial film residues left on the sides of the first gate pattern beneath the second gate pattern. In embodiments, removal of the sacrificial film residues may be carried out through isotropic wet etching.

Embodiments relate to a method that may include forming a lightly doped drain (LDD) region in a semiconductor substrate adjacent to the first and second gate patterns. In embodiments, forming the sidewall spacers may include depositing an insulating film with reduced step coverage over the surface of a semiconductor substrate including a second gate pattern. In embodiments, an insulating film may be anisotropically etched to form sidewall spacers.

Embodiments relate to a semiconductor device that may include at least one of: A gate insulating film on and/or over a semiconductor substrate in a gate region. A gate pattern including a first gate pattern arranged on and/or over the gate insulating film and a second gate pattern arranged on and/or over the first gate pattern, wherein (in embodiments) the second gate pattern is wider than the first gate pattern. Sidewall spacers at both sides of the first gate pattern and second gate pattern. A lightly doped drain (LDD) region at least partially overlapping the gate insulating film, wherein (in embodiments) the LDD is at least partially located in the semiconductor substrate.

In embodiments, a gate pattern may have a predetermined space between each sidewall spacer and the first gate pattern due to the difference in width between the first gate pattern and the second gate pattern.

### DRAWINGS

Example FIGS. 1 to 3 illustrate a semiconductor device and a method of manufacturing the same, in accordance with embodiments.

FIG. 1A is a cross-sectional view illustrating the structure of a transistor including an LDD region.

FIG. 1B is an enlarged cross-sectional view illustrating a portion where an LDD region and a gate region overlap.

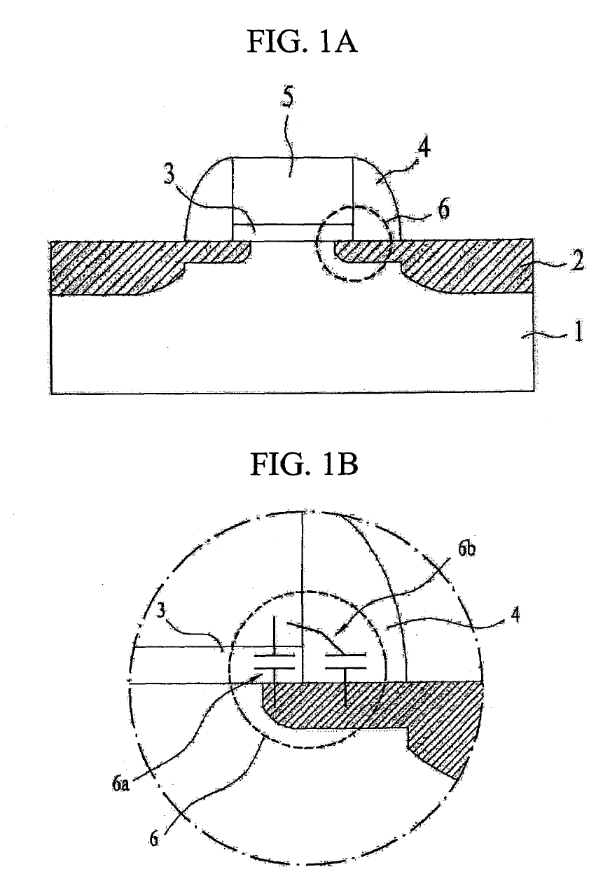

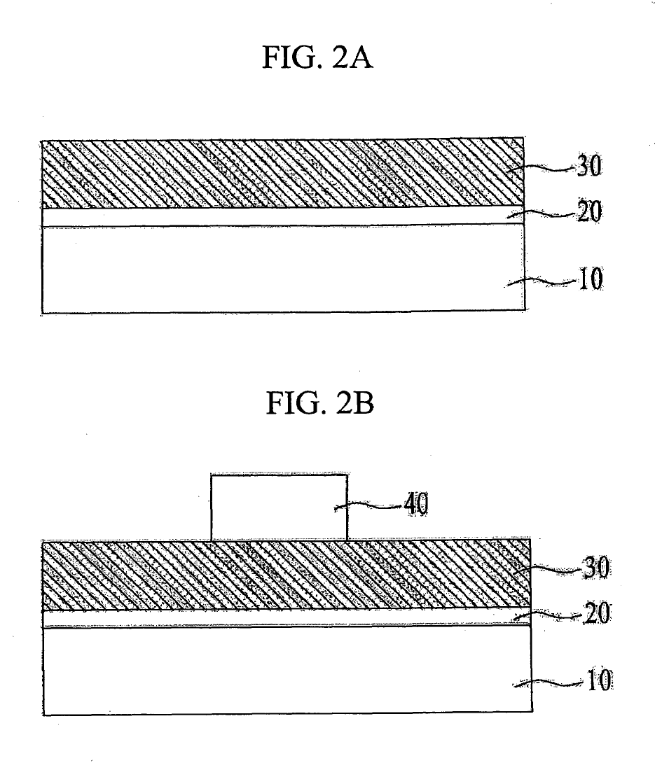

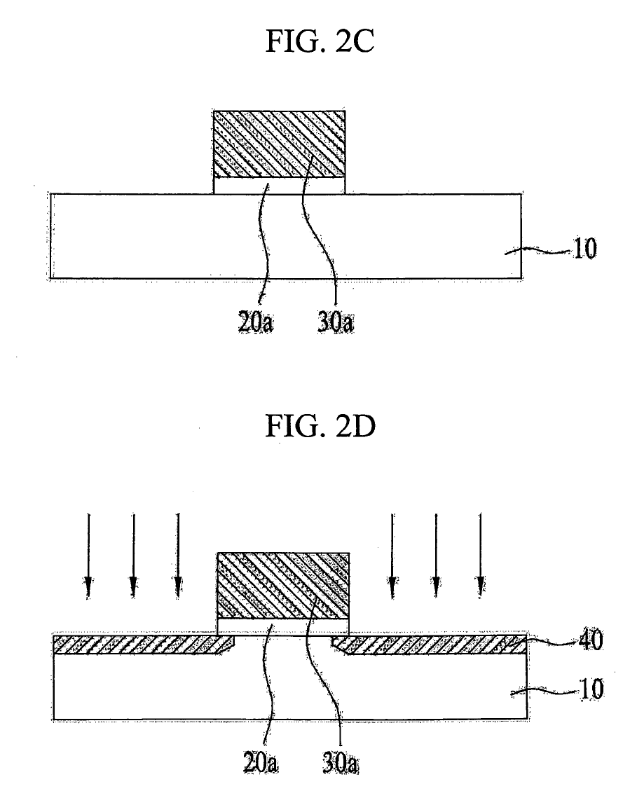

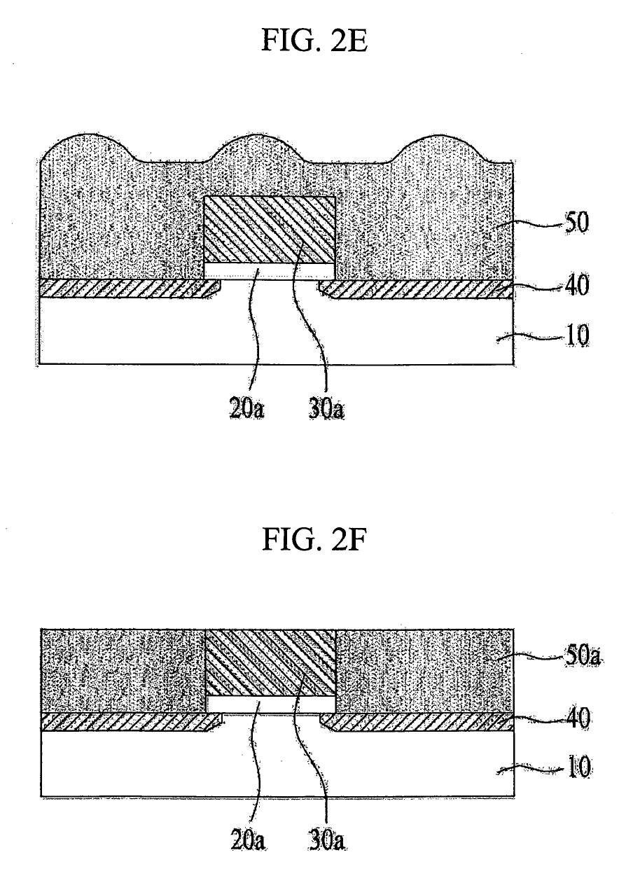

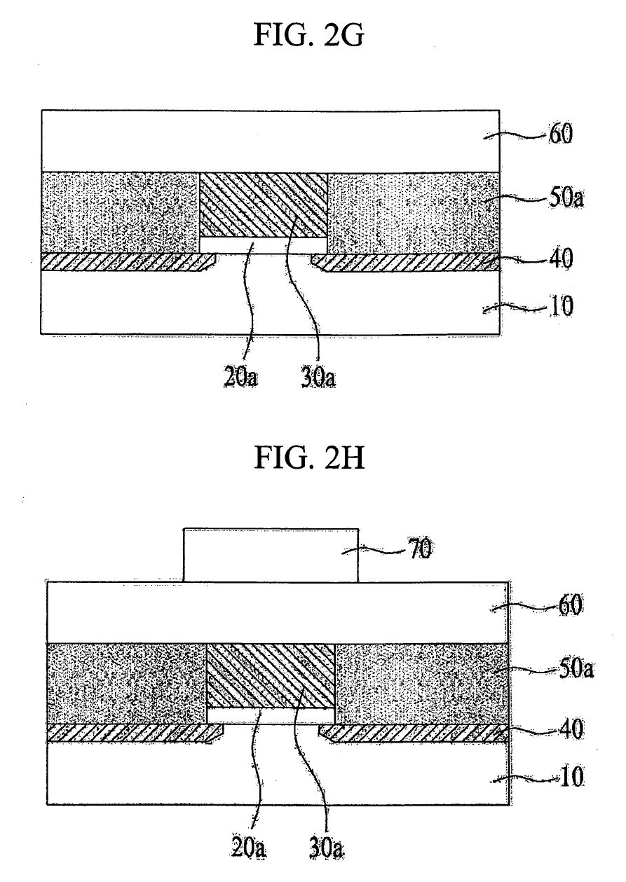

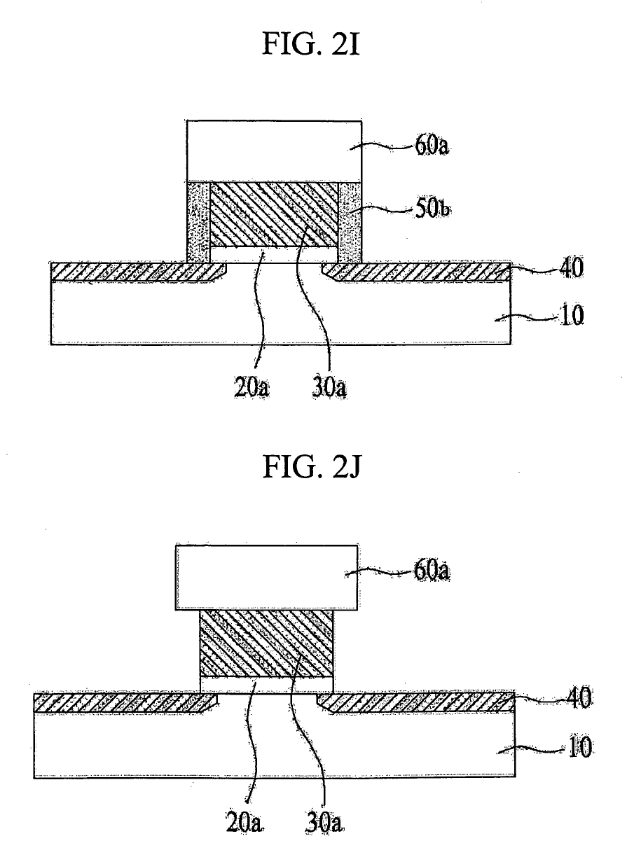

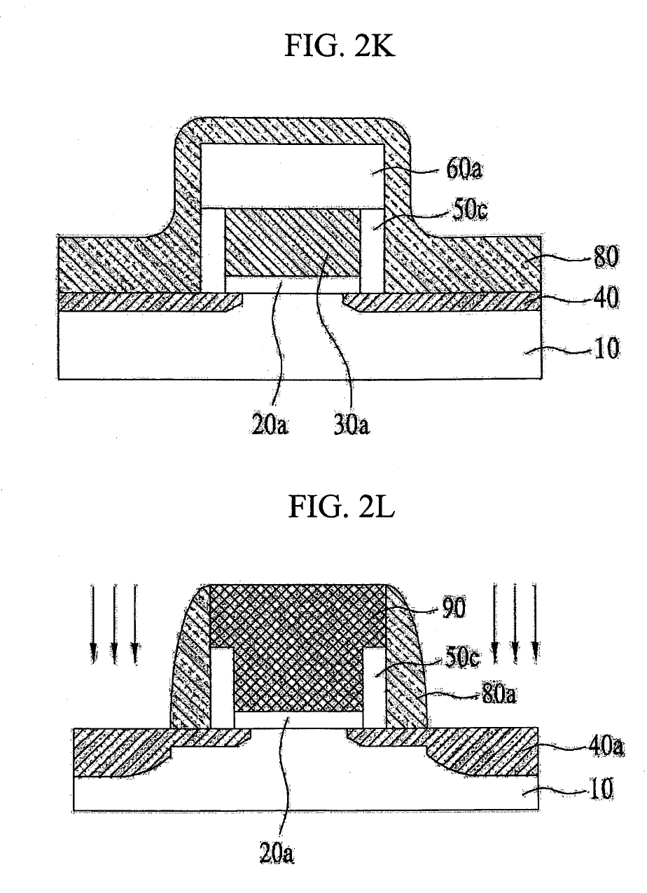

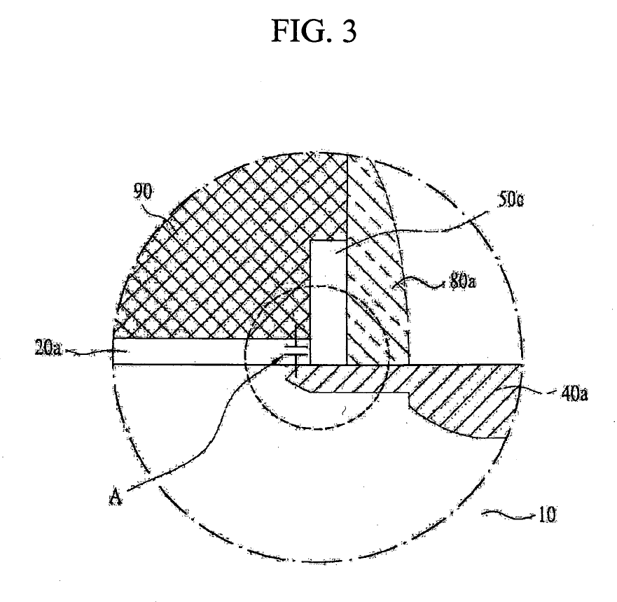

Example FIGS. 2A to 2L are cross-sectional views illustrating a process for manufacturing a semiconductor device, in accordance with embodiments.

Example FIG. 3 is an enlarged cross-sectional view illustrating a portion where an LDD region and a gate region overlap, in accordance with embodiments.

### DESCRIPTION

Other aspects, features and advantages of embodiments will be more clearly understood from the following detailed description taken in conjunction with the accompanying drawings.

Hereinafter, configurations and operations according to embodiments will be described in detail with reference to the accompanying drawings. Although the configurations and functions of embodiments are illustrated in the accompanying drawings, in conjunction with at least one embodiment, and described with reference to the accompanying drawings and the embodiment, the technical idea of the embodiments and the important configurations and functions thereof are not limited thereto.

Example FIGS. 2A to 2L illustrate cross-sectional views of a process of manufacturing a semiconductor device, according to embodiments. FIG. 2L is a cross-sectional view illustrating the structure of a semiconductor device manufactured in accordance with the process illustrated in FIGS. 2A to 2L.

Embodiments may include gate oxide film 20a (e.g. as a gate insulating film) on and/or over a semiconductor substrate 10. A gate pattern 90 (e.g. with a T-shape) may be formed on and/or over gate oxide film 20a. Sidewall spacers 80a may be spaced by gate pattern 90 in a predetermined region. Lightly doped drain (LDD) regions may be formed in semiconductor substrate 10 adjacent to gate pattern 90.

Gate pattern 90 may be deposited through a two-stage deposition process. First gate pattern 30a may be formed before second gate pattern 60a. Second gate pattern 60a may be formed above first gate pattern 30a and second gate pattern 60a may be wider than first gate pattern 30a. In embodiments, a difference in width between first gate pattern 30a and second gate pattern 60a forms T-shaped gate pattern 90. In embodiments, gate oxide film 20a may be formed to have substantially the same width as first gate pattern 30a.

Sidewall spacers 80a may be formed at both sides of the gate pattern 90 and may function to reduce step coverage during deposition of an insulating film (e.g. a silicon oxide (SiO₂) film). In embodiments, sidewall spacers 80a may be formed adjacent to T-shaped gate pattern 90 to form a spaces 50c between sidewall spacers 80a and first gate pattern 30a. Spaces 50c may be formed by both the difference in width between first gate pattern 30a and second gate pattern 60a, and reduced step coverage.

Lightly doped drain (LDD) region may partially overlap gate oxide film 20a. LLD region may be at least partially formed in semiconductor substrate 10 beneath the space 50c and the sidewall spacer 80a.

Hereinafter, a process for manufacturing a semiconductor device will be discussed, in accordance with embodiments. Example FIG. 2A illustrates gate oxide 20 (e.g. as a gate insulator) deposited on and/or over semiconductor substrate 10, in accordance with embodiments. First gate poly 30 may be deposited on and/or over gate oxide 20. Example FIG. 2B illustrates first mask pattern 40 (e.g. a patterned photoresist material) formed on and/or over first gate poly 30, in accordance with embodiments. Example FIG. 2C illustrates first gate poly 30 and gate oxide film 20 selectively etched using first mask pattern 40 to form first gate pattern 30a on and/or over gate oxide film 20a, in accordance with embodiments.

Example FIG. 2D illustrates primary ion-implantation to form a first LDD region 40 (e.g. to form a source/drain), in accordance with embodiments. Example FIG. 2E illustrates a sacrificial film 50 formed on and/or over the surface of semiconductor substrate 10 including first gate pattern 30a. In embodiments, formation of sacrificial film 50 may be carried out by depositing a silicon oxide (SiO₂) film.

Example FIG. 2F illustrates sacrificial film 50a planarized (e.g. by chemical mechanical planarization) from sacrificial film 50, such that the surface of first gate pattern 30a is exposed, in accordance with embodiments. Example FIG. 2G illustrates second gate poly 60 deposited on and/or over sacrificial film 50a and first gate pattern 30a, in accordance with embodiments. Example FIG. 2H illustrates second mask pattern 70 formed on and/or over gate poly 60, in accordance with embodiments. In embodiments, second mask pattern 70 may be formed to be wider than first mask pattern 40.

Example FIG. 2I illustrates second gate poly 60 and the planarized sacrificial film 50a selectively etched using second mask pattern 70 to form second gate pattern 60a and sacrificial film residue 50b. Second mask pattern 70 may be removed after etching second gate poly 60 and planarized sacrificial film 50a. Example FIG. 2J illustrates removal of sacrificial film residue 50b, which was under the second gate pattern 60a near both sidewalls of the first gate pattern 30a, in accordance with embodiments. In embodiments, removal of sacrificial film residue 50b may be performed by isotropic wet etching. Removal of sacrificial film residue 50b may form a T-shaped gate pattern, including an upper second gate pattern 60a with a larger width than a lower first gate pattern 30a.

Example FIG. 2K illustrates insulating film 80 (e.g. for sidewall spacers) with reduced step coverage deposited over semiconductor substrate 10 and second gate pattern 60a, in accordance with embodiments. In embodiments, insulating film 80 may be a silicon oxide (SiO₂) film. Prior to insulating film 80 with reduced step coverage being deposited, the sacrificial film residue 50b may be removed, so that space 50c is formed by insulating film 80, in accordance with embodiments.

Example FIG. 2L illustrates insulating film 80 anisotropically etched to form sidewall spacers 80a, in accordance with embodiments. In embodiments, sidewall spacers 80a are formed at both sides of the first gate pattern 30a and second gate pattern 60a. Spacers 80a may allow space 50c to remain where sacrificial film residue 50b was removed. In embodiments, sidewall spacers 80a may be formed on and/or over semiconductor substrate 10 substantially perpendicular to semiconductor substrate 10, along side surfaces of second gate pattern 60a. In embodiments, sidewall spacer 80a with reduced step coverage may be formed vertically along a side surface of second gate pattern 60a, thereby providing space 50c at one side of the first gate pattern 30a. Secondary ion-implantation (e.g. for source/drain formation) may be performed to form second LDD region 40a, in accordance with embodiments.

Example FIG. 3 is an enlarged cross-sectional view illustrating a portion where an LDD region and a gate region overlap, in accordance with embodiments. In accordance with embodiments, space 50c (e.g. where sacrificial film residue 50b was removed) may minimize and/or substantially eliminate overlap capacitance A and/or fringing capacitance caused by overlap between a LDD region and a gate region.

In embodiments, first gate pattern and second gate pattern with different widths may be formed through a two-step process, which may prevent generation of parasitic capacitance in an area where a LDD region and a gate region overlap, while realizing miniaturization of a semiconductor device. In embodiments, parasitic capacitance (e.g. including fringing capacitance) may be substantially prevented and/or minimized. In embodiments, capacitances of semiconductor devices including transistors may be more accurately estimated. In embodiments, DC/AC parameters may be readily matched and circuits may be easily designed. Transistors related to embodiments may secure high market competitiveness, as compared to transistors with the same size.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming a gate insulating film over a semiconductor substrate in a gate region;
forming a first gate pattern over the gate insulating film;
forming a second gate pattern over the first gate pattern, wherein the second gate pattern is wider than the first gate pattern; and
forming sidewall spacers at both sides of the first gate pattern and the second gate pattern, wherein spaces are formed between the sidewall spacers and the first gate pattern below the second gate pattern.
1b. The method of claim 1, wherein the spaces extend substantially perpendicular to the surface of the semiconductor substrate and along side surfaces of the second gate pattern.

2. The method of claim 1, wherein said forming the second gate pattern comprises forming a sacrificial film over the surface of the semiconductor substrate and the first gate pattern.

3. The method of claim 2, wherein said forming the second gate pattern comprises:
planarizing the sacrificial film such that the upper surface of the first gate pattern is exposed; and
forming a gate poly over the planarized sacrificial film.

4. The method of claim 3, wherein said forming the second gate pattern comprises:
forming a mask pattern over the gate poly, wherein the mask pattern is wider than the first gate pattern;.
etching the gate poly and the sacrificial film using the mask pattern; and
removing the mask pattern.

6. The method of claim 3, wherein said forming the second gate pattern comprises removing sacrificial film residue under the second gate pattern to form the spaces.

7. The method of claim 3, wherein said removing sacrificial film residue comprises isotropic wet etching.

8. The method of claim 1, comprising forming a lightly doped drain (LDD) region in the semiconductor substrate adjacent to the first gate pattern and the second gate pattern.

9. The method of claim 1, wherein said forming the sidewall spacers comprises:
depositing an insulating film with reduced step coverage over a surface of the semiconductor substrate and the second gate pattern; and
anisotropically etching the insulating film.

10. An apparatus comprising:
a gate insulating film formed in a gate region over a semiconductor substrate;
a gate pattern comprising a first gate pattern formed over the gate insulating film and a second gate pattern formed over the first gate pattern, wherein the second gate pattern is wider than the first gate pattern;
sidewall spacers formed at both sides of the second gate pattern; and
a first lightly doped drain (LDD) region at least partially overlapping the gate insulating film, wherein the first lightly doped drain (LDD) is at least partially formed in the semiconductor substrate.

11. The apparatus of claim 10, wherein the gate pattern has predetermined spaces under the second gate pattern between the sidewall spacers and the first gate pattern, wherein the predetermined spaces are formed by the difference in width between the first gate pattern and the second gate pattern.

12. The apparatus of claim 10, wherein:
the sidewall spacers are formed on the semiconductor substrate; and
the sidewall spacers are substantially perpendicular to the semiconductor substrate and formed along a side surface of the second gate pattern.

13. The apparatus of claim 10, wherein the second gate pattern is formed by forming a sacrificial film over the entire surface of the semiconductor substrate including the first gate pattern.

14. The apparatus of claim 13, wherein the second gate pattern is formed by:
planarizing the sacrificial film to expose an upper surface of the first gate pattern; and
forming a gate poly on the planarized sacrificial film.

15. The apparatus of claim 14, wherein the second gate pattern is formed by forming a mask pattern over the gate poly, wherein the mask pattern is wider than the first gate pattern.

16. The apparatus of claim 14, wherein the second gate pattern is formed by:
etching the gate poly and the sacrificial film using the mask pattern; and
removing the mask pattern.

17. The apparatus of claim 14, wherein the second gate pattern is formed by removing sacrificial film residue adjacent to the first gate pattern and under the second gate pattern.

18. The apparatus of claim 13, wherein the second gate pattern is formed by removing sacrificial film residue through isotropic wet etching.

19. The apparatus of claim 10, comprising a second lightly doped drain (LDD) region in the semiconductor substrate adjacent to the first gate pattern, the second gate pattern, and the sidewall spacers.

20. The apparatus of claim 10, wherein the sidewall spacers are formed by:
depositing an insulating film with reduced step coverage over the semiconductor substrate and the second gate pattern; and
anisotropically etching the insulating film.
